(19) United States
(12) Patent Application Publication
(10) Pub. No.: US 2013/0207523 A1
(43) Pub. Date: Aug. 15, 2013

(54) PIEZOELECTRIC DEVICE

(71) Applicant: Nihon Dempa Kogyo Co., Ltd., (US)

(72) Inventor: RYOICHI ICHIKAWA, SAITAMA (JP)

(73) Assignee: NIHON DEMPA KOGYO CO., LTD., TOKYO (JP)

(21) Appl. No.: 13/753,515

(22) Filed: Jan. 29, 2013

(30) Foreign Application Priority Data
Feb. 9, 2012 (JP) 2012-026286

(51) Int. Cl. H01L 41/047

(52) U.S. Cl. CPC H01L 41/047
USPC 310/348

(57) ABSTRACT

A piezoelectric device includes a piezoelectric vibrating piece and a base portion in a square shape. The piezoelectric vibrating piece includes a piezoelectric piece, a pair of excitation electrodes, and a pair of extraction electrodes. The base portion includes a pair of connecting electrodes on a first surface at a side of the piezoelectric vibrating piece and a pair of mounting terminals on a second surface. The base portion has short sides facing one another. The short sides include two pairs of castellations depressed toward a center side of the base portion and two pairs of side surface electrodes on the two pairs of castellations. The two pairs of side surface electrodes connect the first surface and the second surface. One pair of the two pairs of side surface electrodes each connect to the pair of connecting electrodes and the pair of mounting terminals.

### CROSS REFERENCE TO RELATED APPLICATION

This application claims the priority benefit of Japan application serial no. 2012-026286, filed on Feb. 9, 2012. The entirety of the above-mentioned patent application is hereby incorporated by reference herein and made a part of this specification.

### TECHNICAL FIELD

This disclosure relates to a piezoelectric device where a plurality of lid portions and base portions are allowed to be fabricated in a state of wafer.

### DESCRIPTION OF THE RELATED ART

It is preferred that a large amount of surface mount piezoelectric devices can be fabricated at a time. A piezoelectric device disclosed in Japanese Unexamined Patent Application Publication No. 2006-148758 (hereinafter referred to as Patent Literature 1) is fabricated such that a quartz-crystal wafer including a plurality of quartz-crystal vibrating pieces is sandwiched between a lid wafer and a base wafer with the same shape as the quartz-crystal wafer. The piezoelectric device disclosed in Patent Literature 1 includes openings at the lid wafer and the base wafer, and side portion wirings at four corners of the piezoelectric device. The side portion wiring electrically connects an excitation electrode and an external terminal of the quartz-crystal vibrating piece. The piezoelectric devices fabricated on a wafer scale are individually separated for completion.

However, a method for fabricating the piezoelectric device according to Patent Literature 1 forms the side portion wirings at the openings of the base wafer at the same time. Accordingly, if a probe for frequency measurement contacts one piezoelectric vibrating piece among a plurality of piezoelectric vibrating pieces, which are fabricated on a wafer scale, the adjacent piezoelectric vibrating pieces may affect the measurement. That is, the piezoelectric device disclosed in Patent Literature 1 does not allow separately measuring and adjusting the frequency of one of the plurality of piezoelectric vibrating pieces, which are fabricated on a wafer scale. In short, the frequency of one of the piezoelectric vibrating pieces cannot be measured before the piezoelectric vibrating piece is individually separated from the wafer.

When fabricating a piezoelectric device on a wafer scale, the frequency of the piezoelectric vibrating piece is measured on a wafer scale and is adjusted on a wafer scale. Then, it is preferred that the piezoelectric device be individually separated in terms of mass production.

A need thus exists for a piezoelectric device which is not susceptible to the drawback mentioned above.

### SUMMARY

According to a first aspect of this disclosure, there is provided a piezoelectric device. The piezoelectric device includes a piezoelectric vibrating piece and a base portion in a square shape. The piezoelectric vibrating piece includes a piezoelectric piece in a rectangular shape with two principal surfaces, a pair of excitation electrodes on the two principal surfaces, and a pair of extraction electrodes. The pair of extraction electrodes extend from the pair of excitation electrodes to one short side. The base portion includes a pair of connecting electrodes on a first surface at a side of the piezoelectric vibrating piece and a pair of mounting terminals on a second surface. The pair of connecting electrodes connects to the pair of extraction electrodes. The second surface is an opposite surface of the first surface. The base portion has four sides viewed from the first surface. The base portion has short sides facing one another. The short sides include two pairs of castellations depressed toward a center side of the base portion and two pairs of side surface electrodes on the two pairs of castellations. The two pairs of side surface electrodes connect the first surface and the second surface. One pair of the two pairs of side surface electrodes each connect to the pair of connecting electrodes and the pair of mounting terminals.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded perspective view of a quartz-crystal device 100 according to this disclosure;

FIG. 2A is a cross-sectional view taken along the line IIA-IIA of FIG. 1; FIG. 2B is a bottom view of the quartz-crystal device 100;

FIG. 3 is a flowchart illustrating a fabrication method of the quartz-crystal device 100;

FIG. 4 is a plan view of a quartz-crystal wafer 10W;

FIG. 5 is a plan view of a lid wafer 11W;

FIG. 6 is a plan view of a base wafer 12W (the top surface);

FIG. 7A is a partially enlarged plan view of the base wafer 12W according to the related art;

FIG. 7B is a partially enlarged plan view of the base wafer 12W according to this disclosure; and

FIG. 8 is a plan view of the base wafer 12W (the bottom surface).

### DETAILED DESCRIPTION

In this description, an AT-cut quartz-crystal vibrating piece as a piezoelectric vibrating piece is employed. The AT-cut quartz-crystal vibrating piece has a principal surface (in the Y-Z plane) that is tilted by 35° 15′ about the Y-axis of crystallographic axes (XYZ) in the direction from the Z-axis to the Y-axis around the X-axis. The new axes tilted with reference to the axis directions of the AT-cut quartz-crystal vibrating piece are denoted as the Y′ axis and the Z′ axis. This disclosure defines the longer side direction of a crystal unit as the X axis direction, the height direction of the crystal unit as the Y′ axis direction, and the direction perpendicular to the X and Y′ axis directions as the Z′ axis direction.

### Overall Configuration of a Quartz-Crystal Device 100

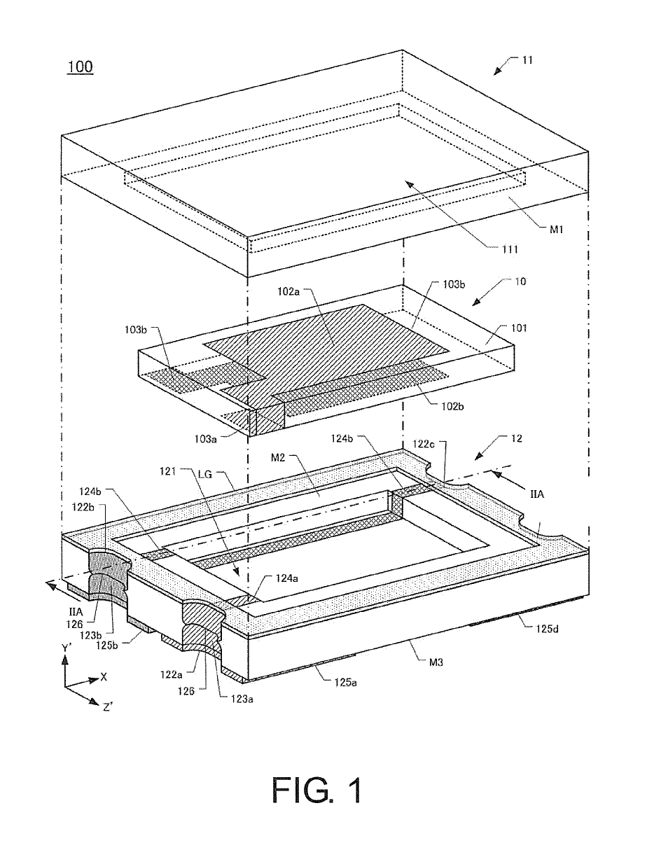

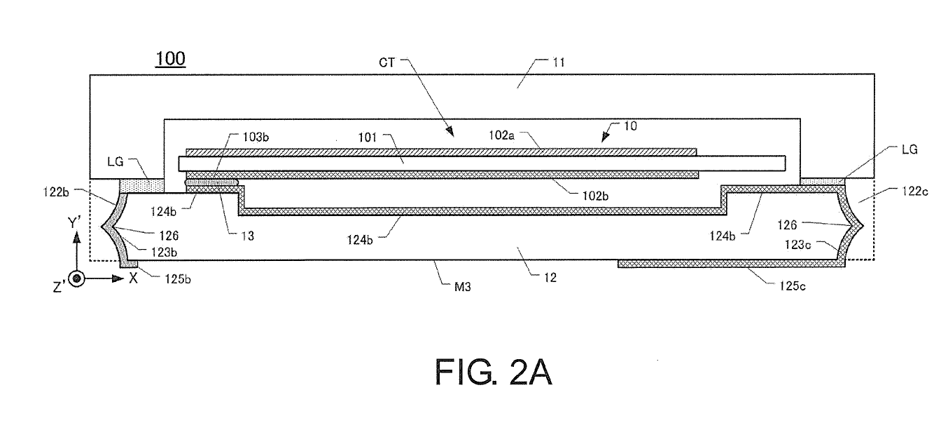

A description will be given of the overall configuration of the quartz-crystal device 100 with referring to FIG. 1 and FIGS. 2A and 2B. FIG. 1 is an exploded perspective view of the quartz-crystal device 100, and FIG. 2A is a cross-sectional view taken along the line IIA-IIA of FIG. 1. In FIG. 1, a low-melting point glass LG, which is a sealing material, is transparent such that the whole connecting electrodes 124a and 124b are viewable.

As illustrated in FIG. 1 and FIG. 2A, the quartz-crystal device 100 includes a lid portion 11, a base portion 12, and a planar quartz-crystal vibrating piece 10. The lid portion 11 includes a lid depressed portion 111. The base portion 12 includes a base depressed portion 121. The quartz-crystal vibrating piece 10 is placed on the base portion 12.

The quartz-crystal vibrating piece 10 includes an AT-cut crystal piece 101. A pair of excitation electrodes 102a and 102b face each other and are disposed on the both principal surfaces of the crystal piece 101 close to the center of the surface. An extraction electrode 103a, which extends to the −X side of the bottom surface of the crystal piece 101 (+Z′ side), connects to an excitation electrode 102a. The extraction electrode 103b, which extends to the +X side of the bottom surface of the crystal piece 101 (−Z′ side), connects to an excitation electrode 102b. The quartz-crystal vibrating piece 10 may be a mesa type or an inverse mesa type.

Here, the excitation electrodes 102a and 102b and the extraction electrodes 103a and 103b, for example, employ a chromium layer as a foundation layer and a gold layer over the top surface of the chromium layer. The chromium layer has a thickness of, for example, 0.05 μm to 0.1 μm, and the gold layer has a thickness of, for example, 0.2 μm to 2 μm.

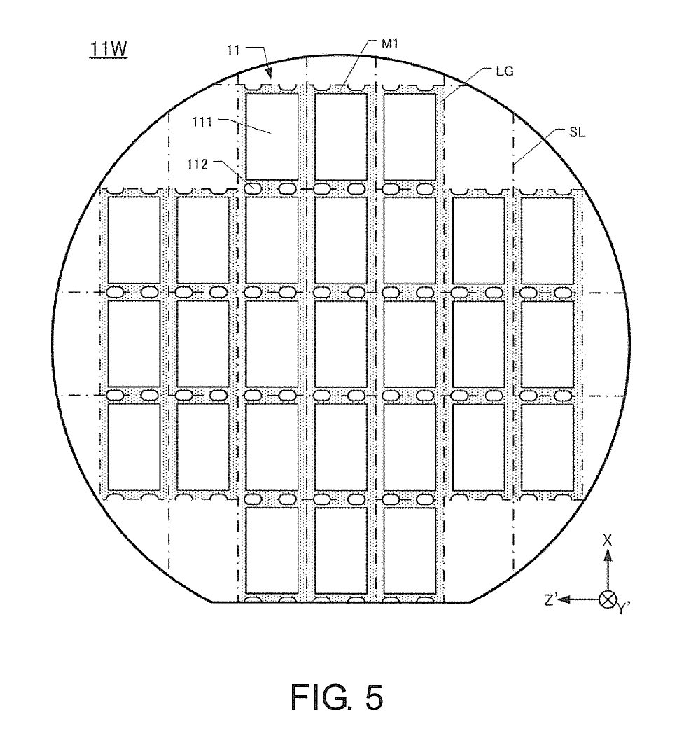

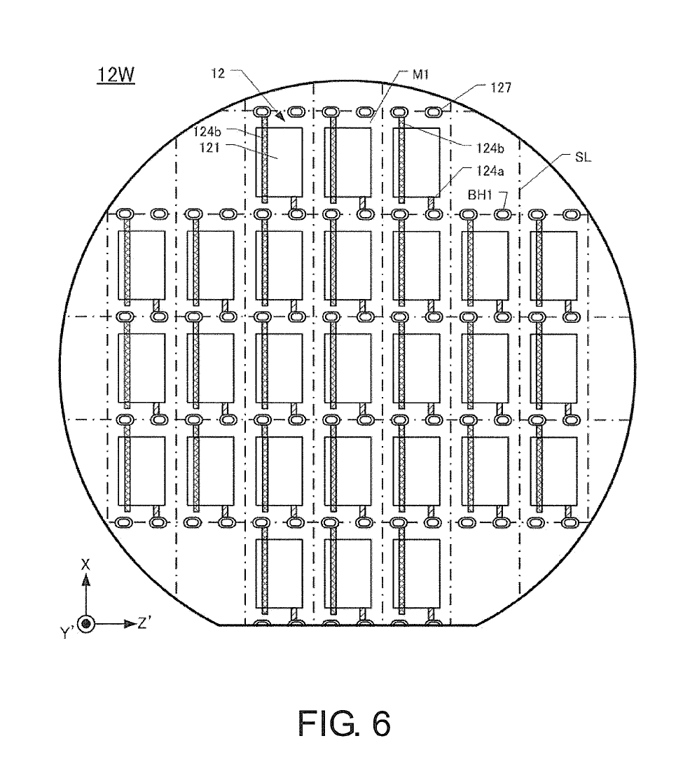

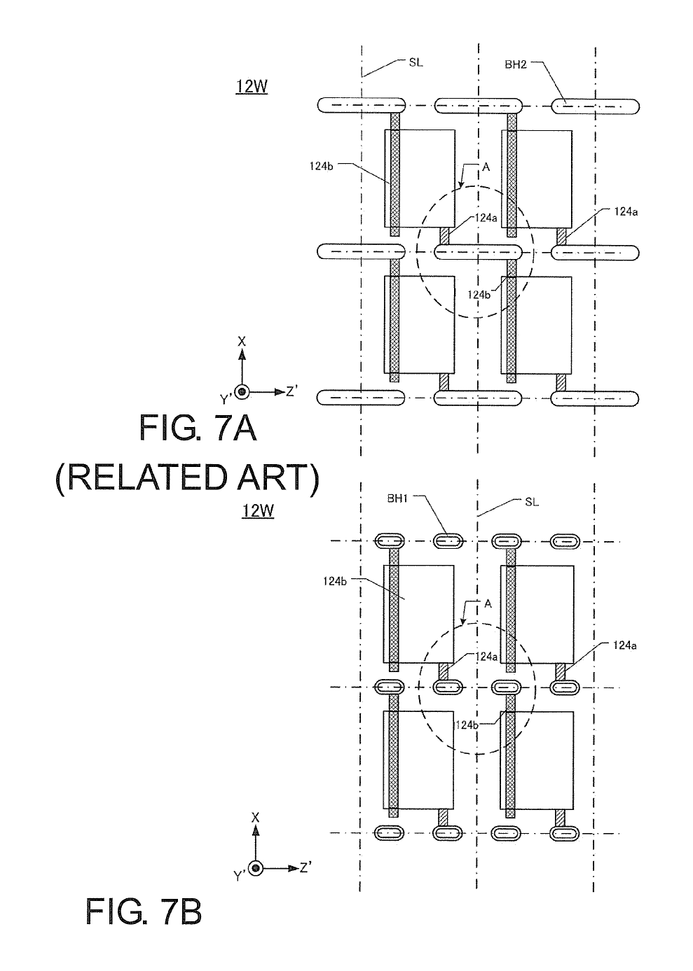

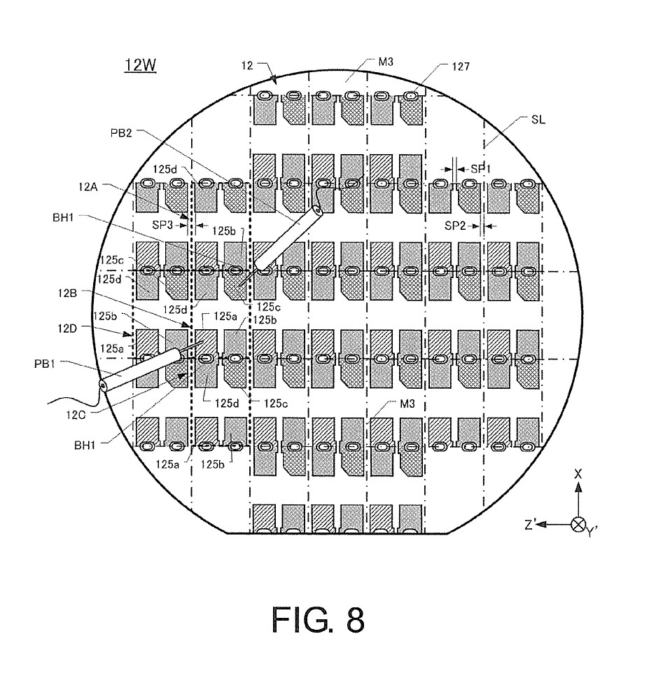

The base portion 12 is made of a glass or a piezoelectric material. The base portion 12 includes a second end surface M2, which is formed at a peripheral area of a base depressed portion 121, on its surface (+Y′ side surface). The base portion 12 also includes two base castellations 122a and 122b at the one side in the −X axis direction. When a base through hole BH1 (see FIG. 6, FIG. 7B, and FIG. 8) is formed, the base castellations 122a and 122b extend in the Z′ axis direction. Here, the base castellation 122a is formed at the +Z side, and the base castellation 122b is formed at the −Z side. Similarly, the base portion 12 includes other two base castellations 122c and 122d at the other side in the +X axis direction. When the base through hole BH1 (see FIG. 6, FIG. 7B, and FIG. 8) is formed, the base castellations 122c and 122d extend in the Z′ axis direction. Here, the base castellation 122c is formed at the −Z side, and the base castellation 122d is formed at the +Z side. That is, the base castellations 122a and 122c are diagonally disposed on the base portion 12, and the base castellations 122b and 122d are diagonally disposed on the base portion 12.

In the base portion 12, tapered projecting portions 126 are formed on the respective base castellations 122a to 122d. The projecting portion 126 protrudes outside at the approximately center portion in the Y′ axis direction. Additionally, base side surface electrodes 123a to 123d are respectively formed at base castellations 122a to 122d.

In this constitution, the base castellations 122a to 122d include an inclined region. This shortens time taken for forming a film when forming the base side surface electrodes 123a to 123d by a method such as sputtering.

The base portion 12 includes a pair of connecting electrodes 124a and 124b formed on the second end surface M2. Here, the connecting electrode 124a electrically connects to the base side surface electrode 123a. The connecting electrode 124b extends in the +X axis direction in the base depressed portion 121. The base side surface electrode 123a electrically connects to a base side surface electrode 123c, which is diagonally disposed on the base portion 12.

Further, the base portion 12 includes two pairs of mounting terminals 125a to 125d on a mounting surface M3. The two pairs of mounting terminals 125a to 125d electrically connect to the base side surface electrodes 123a to 123d, respectively. Among the two pairs of mounting terminals 125a to 125d, one pair of mounting terminals 125a and 125c are diagonally disposed on the base portion 12 and connects to the respective connecting electrodes 124a and 124b via the base side surface electrodes 123a and 123c. The pair of mounting terminals 125a and 125c are each a mounting terminal for external electrode (hereafter referred to as external electrodes). In short, the external electrodes 125a and 125c are diagonally disposed on the base portion 12. Note that, the external electrode 125c has a notch (see FIG. 2B). The notch is fanned to check the orientation of the quartz-crystal device 100. When an alternating voltage (a potential that alternates between positive and negative values of a selected voltage) is applied across the external electrodes 125a and 125c, the quartz-crystal vibrating piece 10 exhibits thickness-shear vibration.

On the other hand, among the two pairs of mounting terminals 125a to 125d, the other one pair is mounting terminals for earth electrode 125b and 125d (hereafter referred to as earth electrodes), which are connected to base side surface electrodes 123b and 123d for grounding. In short, the earth electrodes 125b and 125d are diagonally disposed in a direction different from the external electrodes 125a and 125c on the base portion 12. Here, the earth electrodes 125b and 125d are employed for grounding; however, this disclosure includes the case where the earth electrodes 125b and 125d are employed as terminals that are not electrically connected. The earth electrodes 125b and 125d are employed to strongly bond the quartz-crystal device 100 and a mounting printed circuit board (not shown) together.

The pair of external electrodes 125a and 125c and the pair of earth electrodes 125b and 125d are disposed away from each other as illustrated in FIG. 2B. The external electrode 125a and the earth electrode 125d are formed away from one side at the +Z′ side on the base portion 12. The earth electrode 125b and the external electrode 125c are formed away from the other side at the −Z′ side on the base portion 12. Here, a distance SP1 between the external electrode 125a and the earth electrode 125b, and a distance SP1 between the external electrode 125c and the earth electrode 125d in the Z′ axis direction are each, for example, approximately 100 μm to 250 μm. Additionally, a distance SP2 between the external electrode 125a and the earth electrode 125d and one side at the +Z′ side on the base portion 12; and a distance SP2 between the earth electrode 125b and the external electrode 125c and the other side at the −Z′ side on the base portion 12 are each, for example, approximately 50 μm to 150 μm.

In the quartz-crystal device 100, the length of the quartz-crystal vibrating piece 10 in the X axis direction is longer than the length of the base depressed portion 121 in the X axis direction. Accordingly, when the quartz-crystal vibrating piece 10 is placed on the base portion 12 with conductive adhesive 13, the both ends of the quartz-crystal vibrating piece 10 in the X axis direction is placed on the second end surface M2 of the base portion 12 as illustrated in FIG. 1. At this time, the extraction electrodes 103a and 103b of the quartz-crystal vibrating piece 10 electrically connect to the respective connecting electrodes 124a and 124b of the base portion 12. This electrically connects the external electrodes 125a and 125c to the respective excitation electrodes 102a and 102b via the base side surface electrodes 123a and 123c, the connecting electrodes 124a and 124b, the conductive adhesive 13, and the extraction electrodes 103a and 103b.

The lid portion 11 includes the lid depressed portion 111 and a first end surface M1. The lid depressed portion 111 has an area larger than the base depressed portion 121 in the X-Z′ plane. The first end surface M1 is formed at the peripheral area of the lid portion 11. When the first end surface Ml of the lid portion 11 and the second end surface M2 of the base portion 12 are bonded together, the lid depressed portion 111 and the base depressed portion 121 form a cavity CT. The cavity CT houses the quartz-crystal vibrating piece 10. The cavity CT is filled with an inert gas or is evacuated to a vacuum state.

Here, the first end surface MI of the lid portion 11 is bonded to the second end surface M2 of the base portion 12, for example, with a low-melting point glass LG, which is a sealing material (non-conductive adhesive). The low-melting point glass LG contains lead-free vanadium-based glass that melts at 350° C. to 410° C. The vanadium-based glass is a paste to which binder and flux are added and bonds to another member by melting and hardening.

In the lid portion 11, the length of the lid depressed portion 111 in the X axis direction is longer than the length of the quartz-crystal vibrating piece 10 in the X axis direction and the length of the base depressed portion 121 in the X axis direction. Further, the low-melting point glass LG bonds the lid portion 11 and the base portion 12 together at the outside of the second end surface M2 (the width is approximately 300 μm) of the base portion 12 as illustrated in FIG. 1 and FIG. 2A.

While the quartz-crystal vibrating piece 10 is placed on the second end surface M2 of the base portion 12, the quartz-crystal vibrating piece 10 may be housed in the base depressed portion 121. At this time, the connecting electrodes 124a and 124b extend from the respective base castellations 122a and 122c to the bottom surface of the base depressed portion 121 via the second end surface M2. In this case, the lid portion may be planar where a lid depressed portion is not formed.

### Fabrication Method of the Quartz-Crystal Device 100

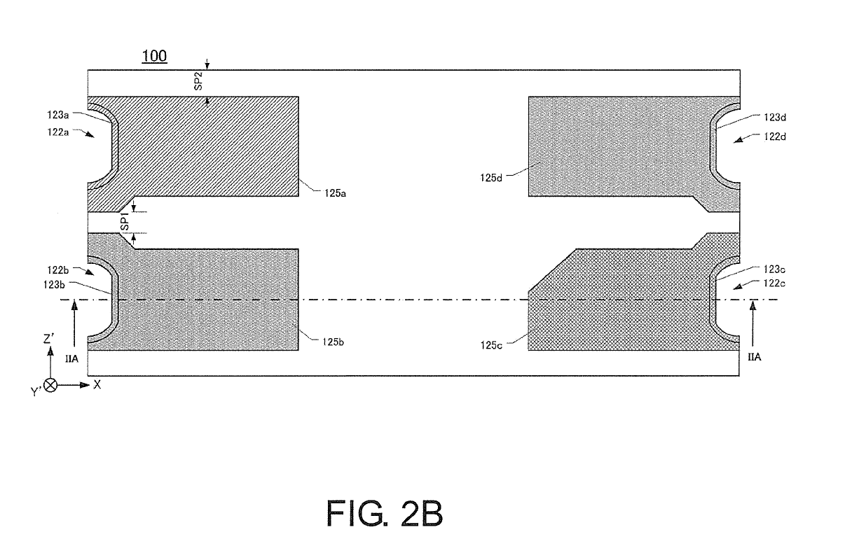

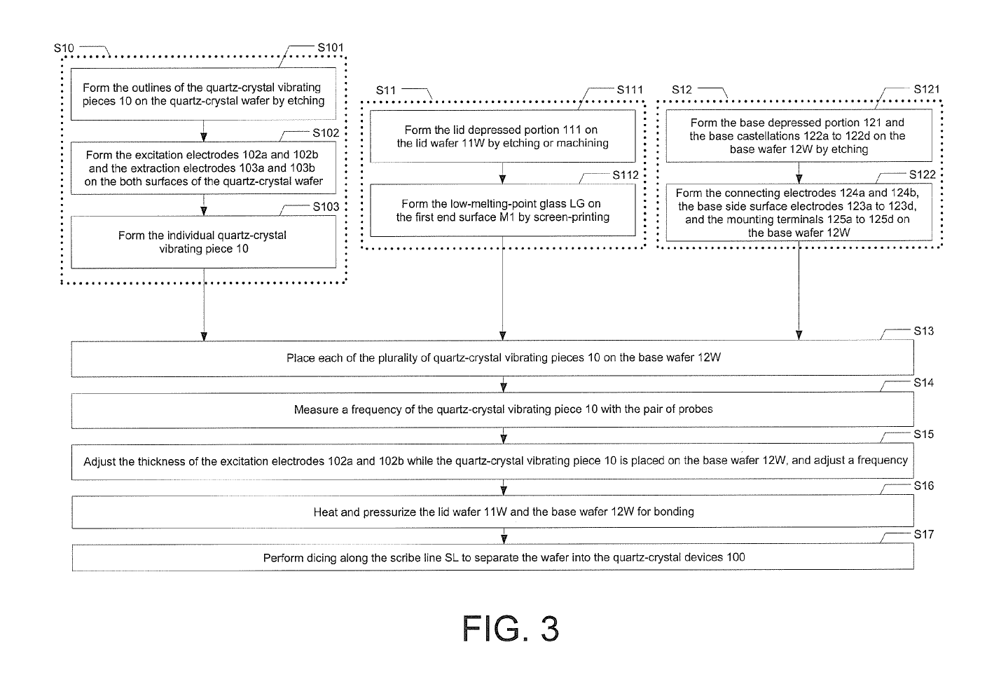

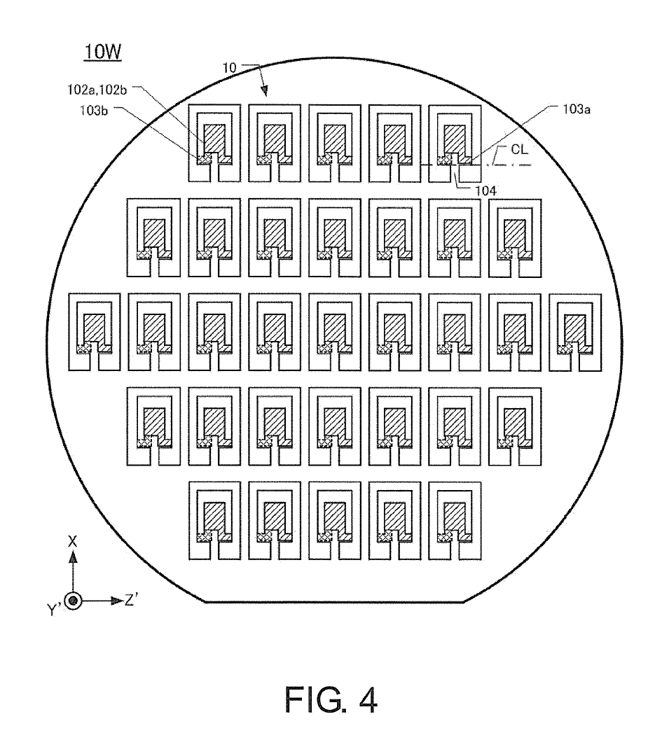

FIG. 3 is a flowchart illustrating a fabrication method of the quartz-crystal device 100. In FIG. 3, the fabrication step of the quartz-crystal vibrating piece 10 (S10), the fabrication step of the lid portion 11 (S11), and the fabrication step of the base portion 12 (S12) can be performed at the same time. FIG. 4 is a plan view of a quartz-crystal wafer 10W where a plurality of quartz-crystal vibrating pieces 10 can be fabricated at the same time. FIG. 5 is a plan view of a lid wafer 11W where a plurality of lid portions 11 can be fabricated at the same time. FIG. 6 is a plan view of a base wafer 12W where a plurality of base portions 12 can be fabricated at the same time. FIG. 8 is a bottom view of the base wafer 12W.

The quartz-crystal vibrating piece 10 is fabricated at step S10. Step S10 includes steps S101 to S103. In step S101, outlines of the plurality of quartz-crystal vibrating pieces 10 are formed on the even quartz-crystal wafer 10W by etching as illustrated in FIG. 4. Here, each quartz-crystal vibrating piece 10 connects to the quartz-crystal wafer 10W with a connecting portion 104.

In step S102, first, a chromium layer and a gold layer are formed in this order on the both surfaces and the side surfaces of the quartz-crystal wafer 10W by sputtering or vacuum evaporation. Then, a photoresist is evenly applied over the all surfaces of the metal layer. Then, the patterns of the excitation electrode and the extraction electrode described on a photomask is exposed onto the quartz-crystal wafer 10W using an exposing device (not shown). Next, the metal layer exposed from the photoresist is etched. This forms excitation electrodes 102a and 102b and extraction electrodes 103a and 103b on the both surfaces and the side surfaces of the quartz-crystal wafer 10W as illustrated in FIG. 4.

In step S103, the quartz-crystal vibrating piece 10 is diced into individual pieces. In the dicing process, the quartz-crystal vibrating pieces 10 is diced along a cut line CL indicated by the one dot chain line illustrated in FIG. 4 using a dicing unit such as a laser beam or a dicing blade.

In step S11, the lid portion 11 is fabricated. Step S11 includes steps S111 and S112. In step S111, several hundred to several thousand of the lid depressed portions 111 are formed on the lid wafer 11W of crystal planar with even thickness as illustrated in FIG. 5. The lid depressed portion 111 is formed on the lid wafer 11W by etching or machining. The first end surface M1 is formed at the peripheral area of the lid depressed portion 111.

In step S112, the low-melting point glass LG is printed on the first end surface M1 of the lid wafer 11W by screen-printing. Then, by temporary hardening of the low-melting point glass LG, the low-melting point glass LG film is formed on the first end surface M1 of the lid wafer 11 W. The low-melting point glass LG film is not formed on a portion 112 corresponding to the base through hole BH1 (the base castellations 122a to 122d in FIG. 1). In this embodiment, the low-melting point glass LG is formed on the lid portion 11; however, the low-melting point glass LG may be formed on the second end surface M2 of the base portion 12.

In step S12, the base portion 12 is fabricated. Step S12 includes steps S121 and S122. In step S121, several hundred to several thousand of the base depressed portions 121 are formed on the base wafer 12W of crystal planar with even thickness as illustrated in FIG. 6. The base depressed portion 121 is formed on the base wafer 12W by etching. The second end surface M2 is formed at the peripheral area of the base depressed portion 121. At the same time, two base through holes BH1 are formed on both sides of each base portion 12 in the X axis direction. The base through hole BH 1 has a rounded rectangular shape and penetrates the base wafer 12W.

In step S121, the base castellations 122a to 122d are formed by etching from the +Y′ side and the −Y′ side. When etching is performed from the +Y′ side, the base depressed portion 121 is formed at the same time. This forms a projecting region 127 at the base through hole BH1 of the base wafer 12W as illustrated in FIG. 6. Dividing the projecting region 127 into half forms the projecting portion 126 (see FIG. 1 and FIG. 2A). Here, when the base through hole BH1 of the rounded rectangular shape is divided into half, one of the base castellations 122a to 122d is formed (see FIG. 1).

In step S122, sputtering from the +Y′ side and the −Y′ side forms the base side surface electrodes 123a to 123d at the base castellations 122a to 122d. Here, since the projecting region 127 is formed at the base through hole BH1, the base side surface electrodes 123a to 123d can be formed at a short period of time (see FIG. 1 and FIGS. 2A and 2B).

In step S122, the gold (Au) layers are formed on the surfaces of the chromium (Cr) layers, which are foundation layers, at the both surfaces of the base wafer 12W by sputtering. Then, etching forms the connecting electrodes 124a and 124b on the second end surface M2 as illustrated in FIG. 6. At the same time, the base side surface electrodes 123a to 123d are formed over all the surfaces of the base through hole BH1 (see FIG. 1).

At the same time, a pair of external electrodes 125a and 125c and a pair of earth electrodes 125b and 125d are formed on the bottom surface of the base wafer 12W as illustrated in FIG. 8. Here, an external electrode and an earth electrode formed adjacent each other in the X axis direction are integrally formed at the base portion 12. Specifically, four base portions (12A to 12D) enclosed by the dotted line in FIG. 8 will be described as one example. The external electrode 125a of a base portion 12B, the earth electrode 125d of a base portion 12C, and the base side surface electrodes 123a and 123d of the base through hole BH1 are integrally formed. Further, the external electrode 125c of the base portion 12B, the earth electrode 125b of the base portion 12A, and the base side surface electrodes 123b and 123c of the base through hole BH1 are integrally formed. Additionally, mounting terminals of the base portion 12B (the external electrode and the earth electrode) are formed away from mounting terminals (the external electrode and the earth electrode) of the base portion 12D, which is adjacent to the base portion 12B in the Z′ axis direction, by a distance SP3. Here, the distance SP3 is approximately 150 μm to 350 μm. Assuming that, for example, the distance SP3 is 200 μm and the width for dicing in step S17, which will be described below, is 40 μm. The distance SP2 indicated in FIG. 2B becomes 80 μm. That is, an external electrode and an earth electrode formed adjacent to each other on the base portion 12 in the X axis direction are connected, while an external electrode and an earth electrode formed adjacent to each other on the base portion 12 in the Z′ axis direction are not connected.

In step S13, the individual quartz-crystal vibrating piece 10, which is fabricated in step S10, is placed on the second end surface M2 of the base portion 12 formed on the base wafer 12W with the conductive adhesive 13. At this time, the quartz-crystal vibrating piece 10 is placed on the second end surface M2 of the base portion 12 so as to align the extraction electrodes 103a and 103b of the quartz-crystal vibrating piece 10 with the connecting electrodes 124a and 124b of the second end surface M2 of the base portion 12. Thus, several hundred to several thousand of the quartz-crystal vibrating pieces 10 are placed on the base wafer 12W.

In step S14, a pair of probes PB1 and PB2 for frequency measurement (see FIG. 8) contact a pair of respective external electrodes 125a and 125c on the same base portion 12, and thus the frequency of each quartz-crystal vibrating piece 10 is measured.

Here, a description will be given with referring to FIGS. 7A and 7B and FIG. 8. Even if an alternating voltage is applied from the probes PB1 and PB2 to the external electrodes 125a and 125c of the base portion 12B, the external electrodes 125a and 125c on the base portions 12A, 12C, and 12D are not electrically connected with each other. The connecting electrodes 124a and 124b enclosed by the dashed line A in FIG. 7B is extracted from the respective independent base through hole BH1. In view of this, the base portions 12A, 12C, and 12D of the quartz-crystal vibrating piece 10 do not affect the base portions 12B. Therefore, a frequency of the quartz-crystal vibrating piece 10 of the base portion 12B can be precisely measured in a state of wafer before dicing. Meanwhile, the shape illustrated in FIG. 7A is in the case where the conventional base through hole BH2 is formed. As illustrated in FIG. 7A, the connecting electrodes 124a and 124b enclosed by the dashed line A are extracted from one opening. In view of this, the piezoelectric device on the wafer is connected to an adjacent piezoelectric device with a side portion wiring.

In step S14, the pair of probes PB1 and PB2 for frequency measurement contact the pair of external electrodes 125a and 125c, respectively, as illustrated in FIG. 8. In contrast, the pair of probes PB1 and PB2 for frequency measurement may contact the pair of connecting electrodes 124a and 124b or the pair of base side surface electrodes 123a and 123c to measure a frequency of the quartz-crystal vibrating piece 10.

In step S15, the thickness of the excitation electrode 102a of the quartz-crystal vibrating piece 10 is adjusted. The thickness can be adjusted by sputtering a metal onto the excitation electrode 102a to increase its mass (and to decrease its frequency), or by evaporating metal from the excitation electrode 102a to decrease its mass (and to increase its frequency) by a reverse sputtering. If the measured frequency result is within its pre-specified proper range, adjustment of the frequency is not required.

In step S14, after a frequency of one quartz-crystal vibrating piece 10 is measured, the frequency of one quartz-crystal vibrating piece 10 may be adjusted in step S15. This sequence is repeated for all the quartz-crystal vibrating pieces 10 on the base wafer 12W. Alternatively, after a frequency of all the quartz-crystal vibrating pieces 10 on the base wafer 12W is measured in step S14, the frequency of the quartz-crystal vibrating pieces 10 may be adjusted one by one in step S15.

In step S16, the low-melting point glass LG is heated by laser or in a reflow furnace, and the lid wafer 11W and the base wafer 12W are pressurized. Thus, the lid wafer 11W and base wafer 12W are bonded together by the low-melting point glass LG.

In step S17, the bonded-together lid wafer 11W and the base wafer 12W are individually diced. In dicing process, use of a dicing unit such as a laser beam or a dicing blade separates the wafer into individual quartz-crystal devices 100 by dicing along the scribe lines SL, denoted by the one dot chain line in FIGS. 5 to 8. This fabricates several hundred to several thousand of the quartz-crystal devices 100.

Representative embodiments are described in detail above; however, as will be evident to those skilled in the relevant art, this disclosure may be changed or modified in various ways within its technical scope.

While in this disclosure, for example, a base wafer, a quartz-crystal wafer, and a lid wafer are bonded together using low-melting point glass, the low-melting point glass may be replaced by a polyimide resin. When using polyimide resin, the fabrication process may be replaced by screen-printing, or an exposure step may be performed after applying photolithographic polyimide resin on the entire surface.

While in this application, a quartz-crystal vibrating piece is used, piezoelectric materials such as lithium tantalite and lithium niobate may be used in addition to quartz-crystal. Further, this disclosure may be directed to piezoelectric oscillators in which an IC accommodating an oscillator circuit is mounted inside the package as a piezoelectric device.

In a piezoelectric device according to a second aspect, the base portion may include a depressed portion depressed from the first surface. The piezoelectric vibrating piece is disposed on the base portion so as to connect the pair of extraction electrodes and the pair of connecting electrodes with a conductive adhesive. In a piezoelectric device according to a third aspect, one of the pair of connecting electrodes extends in a longitudinal direction in the depressed portion.

In a piezoelectric device according to a fourth aspect, the piezoelectric device may further include a lid portion in a square shape having a same size as the base portion. The lid portion is bonded to the first surface of the base portion. The lid portion and the base portion are bonded with a sealing material. In a piezoelectric device according to a fifth aspect, the side surface of the castellation may have a cross-section connecting the first surface and the second surface together. The cross-section has a projecting portion projecting outwardly from a central portion from the first surface to the second surface.

The piezoelectric device according to this disclosure allows separately measuring and adjusting the frequency of each piezoelectric vibrating piece in a state of wafer without being affected by an adjacent piezoelectric device.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric device, comprising:
a piezoelectric vibrating piece; and
a base portion in a square shape, wherein
the piezoelectric vibrating piece comprises:
a piezoelectric piece in a rectangular shape with two principal surfaces;
a pair of excitation electrodes formed on the two principal surfaces; and
a pair of extraction electrodes, the pair of extraction electrodes extending from the pair of excitation electrodes to one short side,
the base portion comprises:
a pair of connecting electrodes formed on a first surface at a side of the piezoelectric vibrating piece and the pair of connecting electrodes connecting to the pair of extraction electrodes; and
a pair of mounting terminals formed on a second surface being an opposite surface of the first surface, and the base portion having four sides viewed from the first surface,
the base portion has short sides facing one another,
the short sides include two pairs of castellations depressed toward a center side of the base portion and two pairs of side surface electrodes are formed on the two pairs of castellations, the two pairs of side surface electrodes connecting the first surface and the second surface, and
one pair of the two pairs of side surface electrodes each connect to the pair of connecting electrodes and the pair of mounting terminals.

2. The piezoelectric device according to claim 1, wherein
the base portion includes a depressed portion depressed from the first surface, and
the piezoelectric vibrating piece is disposed on the base portion so as to connect the pair of extraction electrodes and the pair of connecting electrodes with a conductive adhesive.

3. The piezoelectric device according to claim 1, wherein
one of the pair of connecting electrodes extends in a longitudinal direction in a depressed portion of the base portion, and the depressed portion is depressed from the first surface.

4. The piezoelectric device according to claim 2, wherein
one of the pair of connecting electrodes extends in a longitudinal direction in the depressed portion.

5. The piezoelectric device according to claim 1, further comprising:
a lid portion in a square shape having a same size as the base portion, the lid portion being bonded to the first surface of the base portion; and
the lid portion and the base portion are bonded together with a sealing material.

6. The piezoelectric device according to claim 2, further comprising:
a lid portion in a square shape having a same size as the base portion, the lid portion being bonded to the first surface of the base portion; and
the lid portion and the base portion are bonded together with a sealing material.

7. The piezoelectric device according to claim 3, further comprising:
a lid portion in a square shape having a same size as the base portion, the lid portion being bonded to the first surface of the base portion; and
the lid portion and the base portion are bonded together with a sealing material.

8. The piezoelectric device according to claim 4, further comprising:
a lid portion in a square shape having a same size as the base portion, the lid portion being bonded to the first surface of the base portion; and
the lid portion and the base portion are bonded together with a sealing material.

9. The piezoelectric device according to claim 1, wherein
a side surface of the castellation has a cross-section connecting the first surface and the second surface together, and
the cross-section has a projecting portion projecting outwardly from a central portion from the first surface to the second surface.

10. The piezoelectric device according to claim 2, wherein
a side surface of the castellation has a cross-section connecting the first surface and the second surface together, and
the cross-section has a projecting portion projecting outwardly from a central portion from the first surface to the second surface.

11. The piezoelectric device according to claim 3, wherein
a side surface of the castellation has a cross-section connecting the first surface and the second surface together, and
the cross-section has a projecting portion projecting outwardly from a central portion from the first surface to the second surface.

12. The piezoelectric device according to claim 4, wherein
a side surface of the castellation has a cross-section connecting the first surface and the second surface together, and
the cross-section has a projecting portion projecting outwardly from a central portion from the first surface to the second surface.

13. The piezoelectric device according to claim 5, wherein
a side surface of the castellation has a cross-section connecting the first surface and the second surface together, and
the cross-section has a projecting portion projecting outwardly from a central portion from the first surface to the second surface.

14. The piezoelectric device according to claim 6, wherein
a side surface of the castellation has a cross-section connecting the first surface and the second surface together, and
the cross-section has a projecting portion projecting outwardly from a central portion from the first surface to the second surface.

15. The piezoelectric device according to claim 7, wherein
a side surface of the castellation has a cross-section connecting the first surface and the second surface together, and
the cross-section has a projecting portion projecting outwardly from a central portion from the first surface to the second surface.

16. The piezoelectric device according to claim 8, wherein
a side surface of the castellation has a cross-section connecting the first surface and the second surface together, and
the cross-section has a projecting portion projecting outwardly from a central portion from the first surface to the second surface.
